(19) United States
(12) Patent Application Publication
(10) Pub. No.: US 2017/0018662 A1
(43) Pub. Date: Jan. 19, 2017

(54) PHOTOACTIVE SEMICONDUCTOR COMPONENT AND METHOD FOR PRODUCING A PHOTOACTIVE SEMICONDUCTOR COMPONENT

(71) Applicant: Fraunhofer-Gesellschaft zur Forderung Der Angewandten Forschung E.V., Munchen (DE)

(72) Inventors: Frank FELDMANN, Freiburg (DE); Martin HERMLE, Freiburg (DE)

(73) Assignee: Fraunhofer-Gesellschaft zur Forderung Der Angewandten Forschung E.V., Munchen (DE)

(21) Appl. No.: 15/124,161

(22) PCT Filed: Mar. 6, 2015
(86) PCT No.: PCT/EP2015/054773

§ 371 Date: Sep. 7, 2016

(30) Foreign Application Priority Data
Mar. 21, 2014 (DE) 10 2014 205 350.1

(51) Int. Cl. H01L 31/0216; H01L 31/0368; H01L 31/0288; H01L 31/0376; H01L 31/18; H01L 31/20

(52) U.S. Cl. CPC H01L 31/02167; H01L 31/1812; H01L 31/204; H01L 31/1868; H01L 31/1872; H01L 31/0288; H01L 31/182; H01L 31/03765; H01L 31/03682

(57) ABSTRACT

The invention relates to a photoactive semiconductor component, especially a photovoltaic solar cell, having a semiconductor substrate, a carbon-containing SiC layer disposed indirectly upon a surface of the semiconductor substrate, and a passivating intermediate layer disposed indirectly or directly between the SiC layer and semiconductor substrate, and a metallic contact connection disposed indirectly or directly upon a side of the SiC layer facing away from the passivating intermediate layer and in electrically conductive connection with the SiC layer, where the SiC layer has p-type or n-type doping, which is characterized in that the SiC layer partly has a partly amorphous structure and partly has a crystalline structure.

### BACKGROUND

The invention relates to a photoactive semiconductor component as well as a method for producing a selective contact of a photoactive semiconductor component.

Photoactive semiconductor components are classified as photon absorbing semiconductor components, so-called photovoltaic solar cells and photon emitting semiconductor components, so-called light emitting diodes (LED). Such photoactive semiconductor components typically exhibit a metallic semiconductor contact for the electric contacting of a semiconductor substrate of the semiconductor component. In order to improve the electric features and particularly the effectiveness of the semiconductor component, there is a need for reducing the recombination at the metallic semiconductor contact. This improves the efficiency of the semiconductor component. In particular in case of photovoltaic solar cells the open terminal voltage increases under standard test conditions.

It is known to realize a metallic semiconductor contact for photovoltaic solar cells via so-called selective contacts, which exhibit a low electric contact resistance and simultaneously a low surface recombination speed for minority charge carriers. From M. Tanaka, Japanese Journal of Applied Physics, Vol. 31, No. Part 1, No. 11, p. 3518-3522, 1992, the structure of a so-called HIT solar cell is known (Hereto-junction with Thin Intrinsic Layer). Its passivation is based on the one hand on the saturation of defects given at the silicon surface via a thin, intrinsically amorphous silicon layer and a band bending induced in the crystalline silicon, which is generated by the doped amorphous silicon layer with a band gap greater than the one generated by crystalline silicon. The hydrogen in the hydrogenated amorphous silicon (a-Si:H) is here of decisive importance: It reduces the density of defects at the boundary to silicon as well as the intrinsic and doped layers.

As an alternative selective contact, from US 2012/005547 A1 the use of polycrystalline silicon is known, which comprises carbon (pc-SiC) instead of amorphous silicon. Here, the passivation of the boundary is generated by a thin passivating oxide. Due to the fact that polycrystalline silicon exhibits only a slightly greater band gap than the crystalline semiconductor substrate, the band gap is irrelevant for the passivation. In order to obtain high selectivity, the pc-SiC layers are usually strongly to abnormally doped in order to this way effectively reducing the reinjection of minorities.

### SUMMARY

The invention is based on the objective to provide a photoactive semiconductor component with a selective contact as well as a method for producing a photoactive semiconductor component with a selective contact, which allow improved features in reference to semiconductor components of prior art and/or more beneficial production methods.

This objective is attained in a photoactive semiconductor component as well as a method for producing a selective contact of a photoactive semiconductor component according to one or more features of the invention. Preferred embodiments are discernible from the following description and claims Hereby the wording of all claims is explicitly incorporated in the description by way of reference.

The semiconductor component according to the invention is preferably produced with the method according to the invention and/or a preferred embodiment thereof. The method according to the invention is preferably implemented to embody the semiconductor component according to the invention and/or a preferred embodiment thereof.

The photoactive semiconductor component according to the invention comprises a semiconductor substrate as well as a SiC-layer including carbon, arranged directly on a surface of the semiconductor substrate. Silicon layers comprising carbon and typically called SiC-layers are known per se and described for example in US 2012/005547 A1. In particular, such layers may exhibit a doping, i.e. being p-doped or n-doped.

A passivating intermediate layer is arranged directly or indirectly between the SiC-layer and the semiconductor substrate. Furthermore, the semiconductor component comprises a metallic contacting structure which is arranged directly or indirectly on a passivating intermediate layer at the side facing away from the SiC-layer. The metallic contacting is connected to the SiC-layer in an electrically conducting fashion known per se.

The SiC-layer of the photoactive semiconductor component according to the invention is a doped layer, e.g., it exhibits a p-doping or n-doping type.

It is within the scope of the invention that additional layers or elements are provided to form the photoactive semiconductor component, particularly in order to improve the optic features of the photoactive semiconductor components in a manner known per se, for example by reflection reducing layers and/or structures.

It is essential that the SiC-layer exhibits partially an amorphous structure and partially a crystalline structure.

The invention is based on the acknowledgement of the application that by such a structure considerable disadvantages can be avoided of an amorphous silicon layer on the one hand and a polycrystalline SiC-layer according to prior art on the other hand:

Amorphous silicon effective passivates the crystalline silicon surface only in the hydrogenated condition (a-Si:H). When heating a hydrogenated amorphous silicon layer, here strong effusion of hydrogen occurs, which considerably worsens the passivation features of the layer. Here, after the deposition only temperatures below 250° C. are permissible. Furthermore, in amorphous silicon layers the doping efficiency is limited due to the defects in the amorphous layer. Due to the fact that a certain doping is required to achieve high open terminal voltage and high fill factors, the layers must be doped sufficiently, here. However, excessive integration of doping material leads to worsened passivation so that the precise adjustment of the doping is very important and sets high requirements to the precision of the production process.

When using doped amorphous silicon in combination with thin tunnel oxide layers additional problems may arise: The hydrogenated a-Si:H layers are typically very rich in hydrogen. Additionally, hydrogen is weakly bonded to a-Si:H, and thus very mobile. When now a certain temperature is applied to the layer, during the deposition process and/or the subsequent high-temperature step, effusion of hydrogen occurs, which can result in the so-called blistering of the a-Si layer. This is particularly caused by the different segregation quotients of hydrogen in silicon and/or silicon oxide. Such blistering can considerably damage the amorphous silicon layer and accordingly seriously worsen the electric features of the semiconductor component.

Furthermore, amorphous silicon tends to oxidize upon heating. This leads to the disadvantage that the amorphous silicon layer, for example when entering the oven at normal atmosphere, oxidizes and the layer is converted into SiO₂ partially or completely, and thus it acts as an electric barrier and no metallic contacting can occur any longer.

Another considerable disadvantage of an amorphous silicon layer is the fact that complete crystallization occurs at temperatures exceeding 600° C. This way the advantage of the larger band gap and the corresponding greater selectivity are annulled.

Thus, upon application of an amorphous silicon layer, no high temperature steps are possible any longer.

In particular the application of potential passivation or the execution of so-called tempering steps must occur before applying the amorphous silicon layer, thus some cell structures cannot be realized, leading to costly procedures.

A SiC-layer has the advantage that a hydrogenated SiC-layer also exhibits considerably less hydrogen in reference to a hydrogenated amorphous silicon layer and furthermore hydrogen enters into a C—H-bond in the SiC-layer, which is considerably more stable than the SiH-bonding of the hydrogen of the amorphous silicon layer. By these above-mentioned effects here the risk of blistering is considerably reduced.

Furthermore, the integration of carbon protects the layer from undesired oxidation during the thermal treatment.

Furthermore, unlike an amorphous silicon layer, a SiC-layer is resistant towards some of the acids frequently used during the production of semiconductor components. This way the band width of potential processing steps expands and costs can be saved.

Another advantage of SiC is the fact that it can be deposited amorphously via PECVD, and subsequently crystallized in a high-temperature step. If the SiC layer, as in US 2012/005547 A1, is completely crystallized after deposition in a high-temperature step, this can result in the band gap becoming considerably smaller and thus the passivation is exclusively ensured by the tunnel oxide, which sets higher demands to the oxide and its production process. Here it is furthermore disadvantageous that the complete crystallization of the SiC-layer requires high temperatures (exceeding 1000° C.), which therefore represent a cost-intensive processing step and furthermore can damage other layers, particularly other oxide layers used for better passivation. Furthermore, the complete crystallization of the SiC-layer results in the generation of considerable stress in the layers between the SiC-layer and passivating intermediate layer and/or the semiconductor substrate. This has negative consequences upon the passivating features.

The present invention avoids these disadvantages now in that initially an amorphous, hydrogenated SiC-layer (a-SiC:H) is precipitated and then the SiC-layer is only partially converted via partial crystallization such that the SiC-layer partially exhibits an amorphous structure and partially a crystalline structure.

The characterization amorphous and crystalline silicon refers here to the definitions known per se: Amorphous silicon exhibits a short range order, however no long range order. Crystalline silicon however exhibits a long range order.

The semiconductor component according to the invention can therefore be generated using a cost-effective deposition method, for example by performing a PECVD deposition for producing the SiC-layer.

Furthermore, by the partially amorphous or partially crystalline structure additional advantages result:

As already mentioned, the a-Si:H/c-Si hetero-contact profits from the greater band gap of a-Si:H and thus it is extremely selective in case of sufficient doping of the a-Si:H layer. Here, the largely parasitic absorption in a-Si:H (quasi-direct semiconductor) and the low thermal stability are disadvantageous. The latter is considerably improved by polycrystalline silicon (pc-Si)-contacts, with their passivation not being based on hydrogen. In theory, they should also exhibit a lower parasitic absorption.

However, so far this could not have been shown, because due to the higher diffusion length of minorities the pc-Si layer thickness (>50 nm) was considerably greater than comparable a-Si layer thicknesses (10-20 nm). Furthermore, the selectivity of this contact is lower, because no hetero-structure is formed based on the identically large band gaps as c-Si. When now the pc-Si layer is replaced by a partially crystalline a-SiC layer, here a hetero-structure is yielded and thus a considerably improved selectivity of the contact.

Additionally, the diffusion length of the minority charge carrier is reduced in reference to pc-Si, which allows the use of thin layer thicknesses as for a-Si:H up to 10 nm. Furthermore, this contact is also distinguished from a-Si-H/c-Si hetero-transitions:
1. The partial crystallization of the amorphous layer allows increased doping efficiency, which promotes the selectivity and conductivity of the contact.
2. The band gap can be lower than the one of a-Si:H, however the parasitic absorption in the layer is considerably reduced because the crystalline Si-portions in the layer exhibit a much lower absorption coefficient.
3. The thermal stability of this layer is comparable to pc-Si and/or pc-SiC contacts.

The advantage of this approach towards completely crystalline SiC-layers is primarily given in that much lower thermal budget are required for partial crystallization.

For the complete crystallization, commonly temperatures and temperature periods are used considerably above 1050° C. and/or 60 min., while a partial crystallization can occur already at 800° C., preferably 900° C., with the temperature treatment lasting from 2 minutes to 15 minutes, for example 10 minutes. Additionally, a treatment via RTP (rapid thermal processing) is possible as well, for example at 900° C. for a period ranging from 10 seconds to 60 seconds, particularly for approximately 30 seconds. Such a higher thermal budget (1050° C.) has additionally negative effects upon the homogeneity of the tunnel oxide. The latter is disintegrated during tempering in an oxygen-poor atmosphere at temperatures exceeding 900° C.

In order to allow good passivation in this case, commonly thermally grown oxides with d>2 nm are used. Further, by additionally introducing an intrinsic pc-Si layer here a reduction of the layer tension can be achieved. This can occur by another processing step, for example LPCVD. Although LPCVD represents a comparatively cost-intensive processing step, the thickness of the above-mentioned mentioned pc-Si layer is low however (preferably less than 10 nm, particularly ranging from 2 nm to 10 nm, preferably from 3 nm to 7 nm, particularly amounting to approximately 5 nm) so that only a minor cost increase results, here.

The method according to the invention for producing a selective contact of a photoactive semiconductor component comprises the following processing steps:

In a processing step A, a semiconductor substrate is provided. In a processing step B, a passivating intermediate layer is arranged indirectly or directly on a surface of the semiconductor substrate. In a processing step C, a doped SiC-layer comprising carbon is arranged indirectly and directly on the passivating intermediate layer, and in a processing step D, an arrangement of the metallic contact structure occurs indirectly or directly on the side of the SiC-layer facing away from the passivating intermediate layer.

It is essential that the SiC-layer is partially formed as an amorphous structure and partially as a crystalline structure. This leads to in the above- mentioned advantages.

The portion of the amorphous SiC-bonds ranges preferably from 20% to 80% of the total volume of the SiC layer, preferably from 30% to 50%. In particular, it is advantageous that the remaining volume comprises crystalline Si and SiC. A crystallinity of approx. 20% (i.e. approx. 20% of the total volume is crystalline) is here already sufficient to yield a considerable improvement of the absorption in reference to a-Si:H.

The above-mentioned embodiment of the SiC layer allows optimization, in order on the one hand to overall reduce the disadvantages of an amorphous silicon layer mentioned at the outset and on the other hand a polycrystalline SiC layer.

Preferably the SiC layer is provided as a Si-rich SiC layer, i.e. the SiC layer exhibits excess Si—Si bonds compared to Si—C bonds. Due to the fact that the crystallization temperature of Si is lower than the one of SiC, here temperatures at a range of 900° C. are sufficient to achieve partial crystallization of the SiC layer. Therefore the layer exhibits partial sections, in which no carbon is bonded to silicon atoms. Advantageously the SiC layer exhibits at least in partial section, in which no carbon is bonded to silicon, both amorphous as well as crystalline structures. The scope of the invention includes here that in the partial sections in which carbon is bonded to silicon a completely amorphous structure is given. This is caused in that such partial areas crystallize only at higher temperatures.

The SiC layer exhibits preferably a carbon content of less than 25 atom percent. This way, additionally good electric contacting features (with a low electric contact resistance) of the SiC layer are ensured by metallic contacting. In particular, the carbon ratio of the SiC layer ranges preferably from 5 atom percent to 20 atom percent, further preferred from 7 atom percent to 15 atom percent.

The semiconductor substrate is preferably embodied as a silicon substrate. This way, it can be applied on structures of photovoltaic solar cells and LEDs, known per se, and the scope of the invention also includes to form the semiconductor substrate from a different semiconductor, for example a GaAs-substrate.

Preferably the semiconductor substrate is formed as the base with a base doping, and the SiC layer as the emitter with an emitter doping type opposite the base doping. This way the advantage results that in a simple fashion a pn-transition is formed to the charge carrier separation, which furthermore exhibits high electric qualities. Doping types are the n-type and the here p-type opposite thereto.

In an alternative, preferred embodiment the semiconductor substrate is embodied as the base with a base doping and the SiC layer as a so-called BSF (back surface field) layer by the SiC layer exhibiting a doping of the base doping type. In this preferred embodiment the SiC layer serves therefore on the one hand to form the selective contact and on the other hand to passivate the surface of the semiconductor substrate so that low surface recombination speed is yielded and thus high electric quality of the semiconductor components.

Preferably, the semiconductor substrate comprises doping at the side facing the passivating intermediate layer exhibiting the same doping substance of the SiC layer. This way, the effective surface recombination speed for minority charge carriers of the semiconductor substrate is further reduced. Furthermore, such a doping can be easily achieved by diffusing the doping substance from the SiC layer into the semiconductor substrate.

In another preferred (embodiment) a second SiC layer is arranged directly at the side of the semiconductor facing away from the SiC layer. Furthermore, a second passivating intermediate layer is arranged indirectly or preferably directly between the semiconductor substrate and the second SiC layer. The second SiC layer preferably exhibits a different distribution of amorphous and crystalline portions in reference to the first SiC-layer. In particular, it is advantageous to form the second SiC layer with a higher amorphous volume rate than the first SiC layer, particularly to form the second SiC layer essentially as an amorphous SiC layer (a-SiC layer). Here, the first SiC layer can be optimized, particularly with regards to a low optic absorption in order to allow photons penetrating into the semiconductor component (photovoltaic solar cell) or allowing emission from the semiconductor component (LED). The second SiC layer can however be optimized with regards to the selective features (greater band gap) and thus can exhibit a higher amorphous volume ratio.

The second SiC layer can be embodied similar to the first SiC layer, particularly with regards to thickness, doping, and type of deposition.

The SiC layer preferably exhibits a thickness <30 nm, preferably <20 nm, particularly <15 nm. In particular, it is advantageous to form the SiC layer with a thickness ranging from 5 nm to 15 nm. This way, an optimization is yielded between low absorption loss and advantageous electric features, particularly with regards to surface passivation.

In another preferred embodiment the oxide layer is locally interrupted. This is achieved using temperatures >900° C. Here, advantageously another pc-Si layer is arranged between the oxide and the SiC layer.

This way the advantage results that a thicker passivating intermediate layer can be used and still the desired electric features are ensured by the interrupted sections. In this preferred embodiment the thickness of the passivating intermediate layer ranges preferably from 1 nm to 4 nm, particularly from 2 nm to 3 nm.

As already mentioned, the photoactive semiconductor component can be embodied as a photon-absorbing or photon-emitting component. The embodiment of the semiconductor component according to the invention as a photovoltaic solar cell is particularly advantageous. Experiments of the applicant have shown that here a photovoltaic solar cell with high effectiveness can be formed in a cost-effective fashion. In particular, it is advantageous to switch several semiconductor components formed as photovoltaic solar cells in a solar cell module in a manner known per se and thus to form a solar cell module.

As already mentioned, in the method according to the invention preferably the SiC layer is applied as an amorphous layer and then only partially crystallized. This results in the advantage that cost-effective production methods, particularly preferred PECVD, can be used and still the disadvantages of amorphous silicon layers are essentially avoided.

In a simple and cost-effective fashion the SiC layer is partially crystallized via the influence of heat, i.e. the amorphous structure of the SiC layer is converted partially into a crystalline structure. This occurs preferably by heating the SiC layer to a temperature above 800° C., preferably above 850° C., further preferred above 900° C. This way, as explained above, preferably temperatures above 950° C. are avoided.

In another preferred embodiment a polycrystalline silicon layer is arranged indirectly or directly between a passivating intermediate layer and the SiC layer. This way the advantage results that the oxide layer is protected.

Although a production method must be used for arranging this polycrystalline silicon layer, which is costly in reference to production methods for applying an amorphous silicon layer, however the above-mentioned polycrystalline silicon layer can be embodied considerably thinner than the SiC layer so that only a minor cost increase results. The thickness of this polycrystalline silicon layer is preferably at a range of 5 nm.

Preferably, the polycrystalline silicon layer is deposited via a method known per se, particularly via a LPCVD. Similarly, the polycrystalline silicon layer can be deposited via APCVD (atmospheric pressure chemical vapor deposition).

The polycrystalline silicon layer is preferably also formed as a SiC layer.

The passivating intermediate layer is preferably embodied as an oxide layer, particularly a silicon oxide layer (SiOₓ-layer). Similarly, the passivating intermediate layer can be embodied as a layer system comprising several partial layers, particularly at least one oxide layer and one polycrystalline silicon layer.

The passivating intermediate layer is preferably embodied as a thermally stable passivating intermediate layer, particularly at temperatures exceeding 800° C., particularly above 900° C. This way the advantage results that high temperature steps known per se can also be used after the application of the passivating intermediate layer. In particular it is advantageous that the passivating intermediate layer comprises one or more layers of Al₂O₃-layer, HfAlSiOₓ-layer. Additionally, the passivating intermediate layer can be embodied in a multi-layered form.

### BRIEF DESCRIPTION OF THE DRAWINGS

In the following, additional preferred features and embodiments are described based on exemplary embodiments and the figures. Here are shown:

FIGS. 1A to C a first exemplary embodiment of a method according to the invention;

FIGS. 2A to C a second exemplary embodiment of a method according to the invention, and

FIGS. 3A to D a third exemplary embodiment of a method according to the invention.

### DETAILED DESCRIPTION OF THE PREFERRED EMBODIMENTS

All figures show schematic cross-sections of a semiconductor component, not to scale, and/or a precursor thereof during the production. Identical reference characters mark the same elements or those with identical effects.

### First Exemplary Embodiment

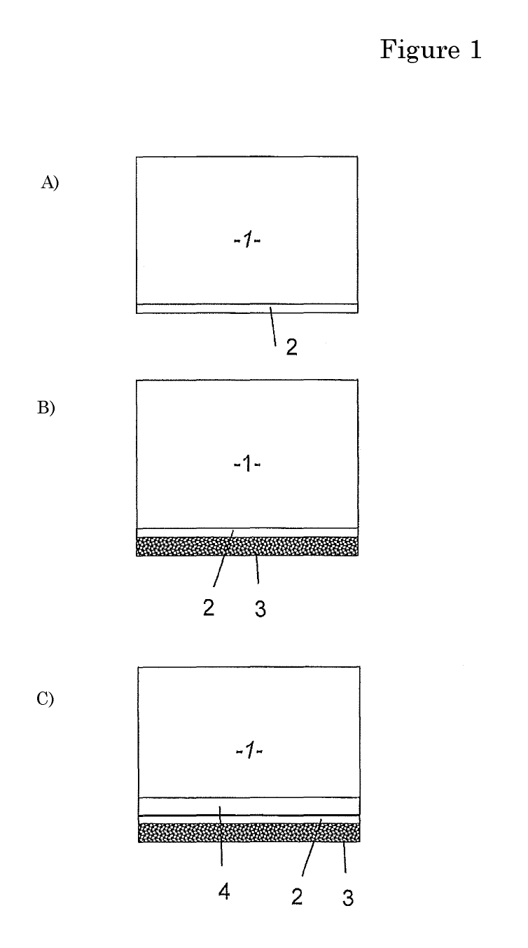

In the first exemplary embodiment of the method according to the invention, shown in FIGS. 1A to C, according to FIG. 1A, a passivating intermediate layer 2, embodied as a tunnel layer, is applied upon a semiconductor substrate 1, embodied as a silicon substrate. The semiconductor substrate 1 is embodied as a monocrystalline silicon wafer. The tunnel layer exhibits a thickness ranging from 5 Angstrom to 50 Angstrom, in the present case 10 Angstrom. It is embodied as a silicon dioxide layer. The tunnel layer may also be embodied as a different oxide. The silicon substrate is embodied as a monocrystalline silicon waver and exhibits in the present case a boron-base doping (p-type) ranging from 10¹⁴ cm⁻³ to 10¹⁷ cm⁻³, in the present case amounting to 1.5×10¹⁶ cm⁻³.

The tunnel layer is applied via wet-chemical growth. Additionally, the tunnel layer may be deposited via RTO (rapid thermal oxidation), ALD (atomic layer deposition), PECVD (plasma enhanced chemical vapor deposition), LPCVD (low pressure chemical vapor deposition), or APCVD (atmospheric pressure chemical vapor deposition).

FIG. 1A shows therefore the status after the execution of exemplary embodiments of the above-mentioned processing steps A and B, in which the tunnel layer was applied directly upon the rear of the semiconductor substrate 1 (shown in FIGS. 1 to 3 respectively laying at the bottom).

In another processing step according to FIG. 1B, a doped amorphous SiC layer 3 is applied (here boron-doped). The carbon portion ranges from approx. 5% to 25%, the present case amounting to approx. 20%.

The thickness of the layer 3 ranges from 5 nm to 30 nm, in the present case amounting to approximately 15 nm. The layer 3 is applied via PECVD. The application of the layers 3 and 4 via LPCVD or APCVD or sputtering is also within the scope of the invention.

The doping of the boron-doped layer ranges here from 10¹⁸ cm⁻³ to 10²¹ cm⁻³.

FIG. 1B shows therefore the status after execution of an exemplary embodiment of the above-mentioned processing step C, in which the doped SiC-layer 3 was applied directly on the tunnel layer 2.

Subsequently, in another processing step (not shown) the solar cell is heated. This way an activation of the doping and partial crystallization of the amorphous SiC layer 3 is yielded. The heating therefore represents a high temperature step, known per se, preferably with temperatures ranging from 600° C. to 950° C., in the present case 800° C.-900° C. The high temperature step is performed via oven tempering. The high temperature step may also be performed via RTP (rapid thermal processing), or by a laser.

The degree of crystallization of the layers can here he controlled by the selected temperature budget and the carbon content in the SiC layer 3. After the heating process the amorphous rate in the overall volume of the layer should amount to at least 20%, preferably >30%, in the present case approximately 40%, in order to ensure improved selectivity due to the increased band gap of a-Si compared to c-Si.

Additionally, during this high-temperature step in an advantageous further development of the exemplary embodiment the doping substance may diffuse from the layer 3 into the substrate in a section 4 such that a shift of the p-n transition and/or the high-low junction (which allows BSF) into the absorber can occur (see FIG. 1C). The exemplary embodiment shown here represents the shift of the high-low junction.

Subsequently (not shown) metallic contact structures are applied on the SiC layer 3, which are connected to the SiC layer 3 in an electrically conductive fashion.

FIG. 1C shows therefore an exemplary embodiment of a semiconductor component according to the invention, with the above-mentioned metallic contacts not being illustrated. In order to finish the semiconductor components as photovoltaic solar cell or LED, additional elements may be added, particularly emitter diffusion (in the present case a n-type, for example using phosphor as the doping substance) at the front of the semiconductor substrate.

In order to avoid repetitions, in the following exemplary embodiments essentially the differences are described.

### Second Exemplary Embodiment

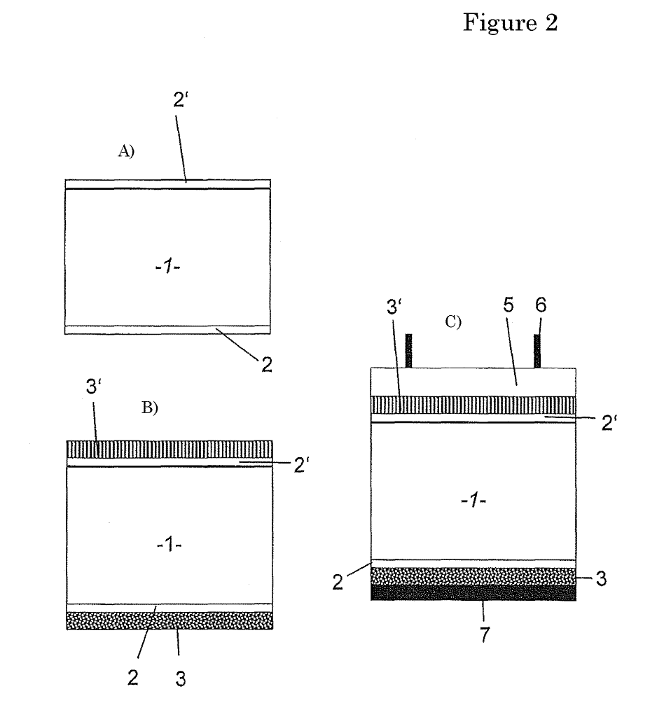

In the second exemplary embodiment of a method according to the invention shown in FIGS. 2A to C, a passivating intermediate layer 2, 2′ is applied according to FIG. 2A, as a tunnel layer onto a semiconductor substrate 1 embodied as a silicon substrate, at both sides. The semiconductor substrate 1 is embodied as a monocrystalline silicon wafer. The tunnel layer exhibits a thickness ranging from 5 Angstrom to 50 Angstrom, in the present case 10 Angstrom. It is embodied as a silicon dioxide layer. The tunnel layer may also be embodied as a different oxide.

The tunnel layer is applied via wet-chemical growth. The tunnel layer may also be deposited via RTO (rapid thermal oxidation), ALD (atomic layer deposition), PECVD (plasma enhanced chemical vapor deposition), LPCVD (low pressure chemical vapor deposition), or APCVD (atmospheric pressure chemical vapor deposition).

In another processing step according to FIG. 2B, a boron-doped amorphous first SiC layer 3 is applied and a phosphor-doped amorphous second SiC layer 3′ (at the front, shown at the top).

The carbon ratio of both layers ranges from approx. 5% to 25%, amounting in the present case to approx. 15%. The thickness of the layers 3 and 3′ ranges from 5 nm to 30 nm, amounting in the present case to approx. 15 nm. The layers are applied via PECVD. Additionally, the scope of the invention includes the application of the layers 3 and 3′ via LPCVD or APCVD or sputtering.

The doping of the n-doped layer 3′ ranges here from 10¹⁸ cm⁻³ to 10²¹ cm⁻³. The same also applies to the p-doped layer 3.

FIG. 1B shows therefore the status at which the two doped SiC layers 3 and 3′ were directly applied on the respective tunnel layer 2.

Subsequently heating of the solar cell occurs (not shown) in another processing step. This way an activation of the doping and partial crystallization of the amorphous SiC layers 3 and 3′ is yielded. The heating represents therefore a high-temperature step known per se, preferably with temperatures at a range 600-950° C., preferably 800-900° C. The high-temperature step is performed via the temperature control of the oven. The high-temperature step can also occur via RTP (rapid thermal processing) or by a laser. The degree of crystallization of the layers may here be controlled by the selected temperature budget and the carbon content in the respective layers 3 and 4. Preferably the layer exhibits at the side facing the light a higher crystalline silicon ratio than the layer at the side facing away from the light. This is caused in the lower absorption coefficient of c-Si compared to a-Si.

The respective amorphous rate in reference to the total volume of both layers should preferably be at least 20%, preferably >30%, in the present case approx. 50%, in order to ensure improved selectivity based on the increased band gap of a-Si compared to c-Si.

Additionally, during this high-temperature step the doping substance can diffuse into the layers 3 and 3′ and into the semiconductor substrate (absorber) such that a shift may occur of the p-n transition into the absorber, similar to the one described in FIG. 1C.

In another processing step according to FIG. 2C, a TCO-layer 5 is applied. This TCO-layer serves to generate the lateral conductivity and to improve the coupling of incident light. This layer 5 may be embodied as ITO, AZO, IO:H, and exhibits a thickness of approx. 70 nm.

Subsequently, at the front a metallic layer 6 is applied in the form of a contacting grid (metallic contacting structure) for example via serigraphy. At the rear, a metallic layer 7 is applied, preferably Ag, over the entire area.

FIG. 2C therefore represents a second exemplary embodiment of a semiconductor component according to the invention.

### Third Exemplary Embodiment

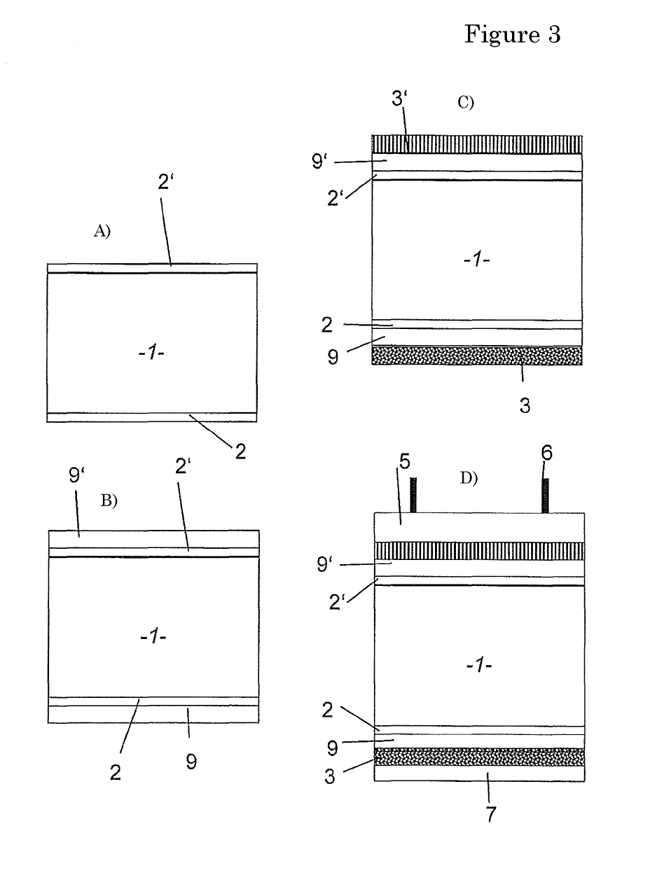

In the exemplary embodiment shown in FIGS. 3A to D which show a method according to the invention, according to FIG. 3A, a tunnel layer 2 is applied at both sides on a semiconductor substrate 1 embodied as a silicon substrate. The semiconductor substrate 1 is embodied as a monocrystalline silicon wafer. The tunnel layer 2 exhibits respectively a thickness ranging from 5 Angstrom to 50 Angstrom, in the present case 10 Angstrom. It is embodied as a silicon dioxide layer. The tunnel layer may also be embodied as a different oxide.

The tunnel layer is applied via wet-chemical growth. The tunnel layer may also be deposited via RTO (rapid thermal oxidation), ALD (atomic layer deposition), PECVD (plasma enhanced chemical vapor deposition), LPCVD (low pressure chemical vapor deposition), or APCVD (atmospheric pressure chemical vapor deposition).

In another processing step according to FIG. 3B, at both sides an un-doped polycrystalline Si-layer (9 and 9′) is applied. The thickness of this layer ranges respectively from 5 nm to 20 nm, amounting in the present case to approx. 5 nm. The layers 9, 9′ are preferably applied via LPCVD. A deposition via APCVD is also within the range of the invention.

In another processing step according to FIG. 3C, a boron-doped amorphous SiC-layer 3 and a phosphor-doped amorphous SiC-layer 3′ is applied. The carbon atom ratio ranges respectively from approx. 5% to 25%, in the present case amounting to approx. 15%.

The thickness of the layers 3 and 3′ ranges from 5 nm to 30 nm, amounting in the present case to approx. 15 nm. The application occurs via PECVD. Similarly, the application of the layers 3 and 3′ via LPCVD or APCVD or sputtering is within the scope of the invention as well. The doping of the n-doped layer ranges here from 10¹⁸ cm⁻³ to 10²¹ cm⁻³. The same also applies to the p-doped layer.

Subsequently in another processing step the solar cell is heated (not shown). This way an activation of the doping and partially the crystallization of the amorphous SiC layers 3 and 3′ is yielded. The heating therefore represents a high-temperature step known per se, preferably with temperatures ranging from 600 to 950° C., in the present case 800-900° C. The high-temperature step is performed via temperature control of the oven. The high temperature step can also occur via RTP (rapid thermal processing) or by a laser. The degree of crystallization of the layers can here be controlled by the selected temperature budget and the carbon content in the respective layers 3 and 3′. Preferably the layer exhibits at the side facing the light a higher crystalline silicon rate than the layer on the side facing away from the light. This is caused by the lower absorption coefficient of c-Si compared to a-SI. The respective amorphous rate refers to the total volume of both layers should preferably amount to at least 20%, preferably >30%, and amounts preferably to approx. 50% in order to ensure improved selectivity based on the increased band gap of a-Si compared to c-Si.

Additionally during this high-temperature step the doping substance of the layer 3 and 3′ can diffuse into the polycrystalline Si-layer 9 and 9′. The advantage of inserting a poly-Si intermediate layer is caused in the different thermal expansion coefficients of Si and SiC. This way, excessive generation of layer tension is prevented by the poly-Si layer, which can have negative effects upon the boundary passivation.

In another processing step according to FIG. 3D, a TCO-layer 6 is applied. This TCO-layer serves for generating lateral conductivity as well as better coupling of the incident light. This layer 6 can be embodied as ITO, AZO, IOH and exhibits a thickness of approx. 70 nm.

Subsequently, a metallic contacting 6 is applied at the front in the form of a contacting grid, for example via serigraphy. At the rear, a metallic layer 7 is applied, preferably Ag, over the entire surface.

FIG. 3D therefore represents a third exemplary embodiment of a semiconductor component according to the invention.

1. A photoactive semiconductor component, comprising a semiconductor substrate, a SiC layer containing carbon and arranged indirectly on a surface of the semiconductor substrate, a passivating intermediate layer indirectly or directly arranged between the SiC layer and the semiconductor substrate, and a metallic contacting, which is arranged indirectly or directly on a side of the SiC layer facing away from the passivating intermediate layer and connected to the SiC layer in an electrically conductive fashion, the SiC layer exhibiting a p-type or n-type doping, and the SiC layer comprises partially an amorphous structure and partially a crystalline structure.

2. The semiconductor component according to claim 1, wherein an amorphous volume of the SiC layer ranges from 20% to 80%, of a total volume of the SiC layer, and a non-amorphous volume of the SiC layer essentially exhibits a crystalline structure.

3. The semiconductor component according to claim 1, wherein the SiC layer exhibits a carbon content of less than 25 atom percent.

4. The semiconductor component according to claim 1, wherein the semiconductor substrate is embodied as a base with a base doping and the SiC layer is embodied as an emitter with a doping type opposite the base doping, or the semiconductor substrate is embodied with a base with a base doping and the SiC layer is embodied as a BSF layer by the SiC layer exhibiting a doping of the base doping type.

5. The semiconductor component according to claim 1, wherein the semiconductor substrate exhibits a doping at a side facing the passivating intermediate layer with a same doping substance of the SiC layer.

6. The semiconductor component according to claim 1, wherein a second SiC layer is arranged indirectly at a side of the semiconductor substrate facing away from the SiC layer and a second passivating intermediate layer is arranged indirectly or directly between the semiconductor substrate and the second SiC layer, with the second SiC layer having a higher amorphous volume ratio in reference to the first SiC layer.

7. The semiconductor component according to claim 1, wherein the SiC layer has a thickness below 30 nm.

8. A semiconductor component according to claim 1, wherein the passivating intermediate layer has a thickness ranging from 1 nm to 5 nm.

9. The semiconductor component according to claim 1, wherein the semiconductor component is embodied as a photovoltaic solar cell.

10. A method for the production of a selective contact of a photoactive semiconductor component, comprising the following processing steps:
A providing a semiconductor substrate;
B arranging a passivating intermediate layer indirectly or directly on a surface of the semiconductor substrate;
C arranging a carbon containing, doped SiC layer indirectly or directly on the passivating intermediate layer, and
D arranging a metallic contacting structure indirectly or directly on a side of the SiC layer facing away from the passivating intermediate layer, and
the SiC layer is partially embodied as an amorphous structure and partially as a crystalline structure.

11. The method for producing a selective contact of a photoactive semiconductor component according to claim 10, wherein the SiC layer is applied as an amorphous layer and subsequently only partially crystallized.

12. The method for producing a selective contact of a photoactive semiconductor component according to claim 10, the SiC layer is crystallized using heat.

13. The method for producing a selective contact of a photoactive semiconductor component according to claim 10, wherein a polycrystalline silicon layer is arranged indirectly or directly between the passivating intermediate layer and the SiC layer.

14. The method for generating a selective contact of a photoactive semiconductor component according to claim 10, wherein the passivating intermediate layer comprises one or more of the layers SiOₓ, Al₂O₃, HfAlOₓ, HfSiOₓ.

15. The method for generating a selective contact of a photoactive semiconductor component according to claim 10, wherein the SiC layer is precipitated via PECVD.

16. The semiconductor component according to claim 3, wherein at least the silicon range of the SiC layer in which no carbon is bonded exhibits both amorphous as well as crystalline structures.

17. The method for producing a selective contact of a photoactive semiconductor component according to claim 12, wherein at least the SiC layer is heated to a temperature above 800° C.
